(19) United States
(12) Patent Application Publication
(10) Pub. No.: US 2002/0038726 A1
(43) Pub. Date: Apr. 4, 2002

(54) Polymer stud grid array and method for producing such a polymer stud grid array

(76) Inventor: Jozef Van Puymbroeck, Oostkamp (BE)

Correspondence Address: LERNER AND GREENBERG, P.A., Post Office Box 2480, HOLLYWOOD, FL, 33022-2480, US

(21) Appl. No.: 09/793,788

(22) Filed: Feb. 26, 2001

(30) Foreign Application Priority Data
Sep. 29, 2000 (DE) 100 48 489.1

(51) Int. Cl. H05K 1/11

(52) U.S. Cl. 174/267; 174/262; 174/264; 174/266

(57) ABSTRACT

A first wiring layer and metallized plated-through holes are formed in/on a substrate. A substrate layer is then applied to the top of the substrate by injection molding, during which an injected material passes through the plated-through holes, resulting in polymer studs being produced on an underside of the substrate. A second wiring layer, formed on the substrate layer, is electrically conductively connected to the first wiring layer by blind plated-through holes, and hence to external connections on the polymer studs by the plated-through holes.

### BACKGROUND OF THE INVENTION

### FIELD OF THE INVENTION

Integrated circuits are being provided with ever higher numbers of connections and are being miniaturized to an ever increasing extent at the same time. The difficulties in terms of application of solder paste and component fitting which are expected with this increasing miniaturization are intended to be overcome by new package forms, with single-chip, few-chip or multi-chip modules in a ball grid array package being mentioned here, see the reference DE-Z Productronic 5, 1994, pages 54, 55. These modules are based on a plated-through substrate on which contact is made with the chips, by way of example, via contacting wires or by flip-chip mounting. The underside of the substrate holds the ball grid array (BGA), which is frequently also called a solder grid array or solder bump array. The ball grid array contains solder studs disposed in a planar fashion on an underside of the substrate, which permit surface mounting on the printed circuit boards or assemblies. Disposing the solder studs in a planar fashion makes it possible to provide large numbers of connections in a coarse grid of, by way of example, 1.27 mm.

In so-called molded interconnection device (MID) technology injection-molded parts with integrated conductor runs are used instead of conventional printed circuits. High-quality thermoplastics, which are suitable for injection molding three-dimensional substrates, form the basis of this technology. Such thermoplastics are distinguished over conventional substrate materials for printed circuits by having better mechanical, chemical, electrical and environmental properties. In one preferred direction of MID technology, a metal layer applied to the injection-molded parts is structured, dispensing with the otherwise normal masking technique, by a special laser structuring method. In this case, a number of mechanical and electrical functions can be integrated into the three-dimensional injection-molded parts with structured metallization. The package support functions are at the same time carried out by guides and snap connections, while the metallization layer is used not only for the wiring and connection function but also for electromagnetic shielding, and ensures good heat dissipation. To produce electrically conductive cross connections between two wiring systems on opposite surfaces of the injection-molded parts, appropriate plated-through holes are produced during the actual injection molding. When the injection-molded parts are metallized, the inner walls of these plated-through holes are then likewise coated with a metal layer.

Further details relating to the production of three-dimensional injection-molded parts with integrated conductor runs can be found, for example, in Published, Non-Prosecuted German Patent Application DE 37 32 249 A1 or in Published, European Patent Application EP 0 361 192 A.

International Patent Disclosure WO 89/00346 discloses a single-chip module in which the injection-molded, three-dimensional substrate made of an electrically insulating polymer has studs which are also formed on the underside of the substrate during injection molding and, if required, may also be disposed in a planar fashion. Disposed on the top of the substrate is an IC chip whose connections are connected via fine bonding wires to interconnects formed on the top of the substrate. For their part, the interconnects are connected via plated-through holes to associated external connections formed on the studs.

International Patent Disclosure WO 96/09646 discloses a so-called polymer stud grid array (PSGA) which combines the advantages of a ball grid array (BGA) with the advantages of MID technology. In this case, the new physical form was called a polymer stud grid array (PSGA) on the basis of the ball grid array (BGA), with the term “polymer stud” being intended to refer to polymer studs which are formed at the same time as the substrate is injection molded. The new physical form suitable for single-chip, few-chip or multi-chip modules contains an injection-molded, three-dimensional substrate made of an electrically insulating polymer. The polymer studs are disposed in a planar fashion on the underside of the substrate and are also formed during the injection molding. External connections are formed on the polymer studs by a solderable end surface. Conductor runs which are formed at least on the underside of the substrate and connect the external connections to internal connections are provided. And at least one chip which is disposed on the substrate and whose connections are electrically conductively connected to the internal connections is provided.

In addition to simple and cost-effective production of the polymer studs during the injection molding of the substrate, the production of the external connections on the polymer studs can also be carried out with minimal effort, together with the normal production of the conductor runs using MID technology. The preferred laser fine structuring allows the external connections to be provided on the polymer studs with large numbers of connections in a fine grid. It should also be stressed that the thermal expansion of the polymer studs corresponds to the thermal expansions of the substrate and of the wiring which holds the module. Therefore the solder connection is very reliable, even with frequent temperature fluctuations.

The substrate of the polymer stud grid array known from International Patent Disclosure WO 96/09646 may also be provided with plated-through holes, so that the polymer studs and the chip or chips can be disposed entirely on different sides of the substrate. In this case, the conductor runs between the polymer studs and the upward-routed plated-through holes are very short, which is an advantage, particularly for radio frequency applications.

### SUMMARY OF THE INVENTION

It is accordingly an object of the invention to provide a polymer stud grid array and a method for producing such a polymer stud grid array which overcome the above-mentioned disadvantages of the prior art devices and methods of this general type, which has the shortest possible connections between the top and the underside and is thus also suitable for radio frequency applications.

With the foregoing and other objects in view there is provided, in accordance with the invention, a polymer stud grid array containing an electrically insulating substrate having a top side and an underside. The electrically insulating substrate has metallized plated-through holes formed therein that extend between the top side and the underside. A first wiring layer is disposed on the top side of the electrically insulating substrate. An injection-molded electrically insulating substrate layer is disposed on the top side of the electrically insulating substrate and has a top surface. The substrate layer has blind plated-through holes formed therein. Polymer studs are disposed in a planar fashion on the underside of the electrically insulating substrate and extend from the metallized plated-through holes. The polymer studs are formed from the substrate layer pushing through the metallized plated-through holes when the substrate layer is injection molded. A second wiring layer is disposed on the top surface of the substrate layer, the blind plated-through holes extend between the first wiring layer and the second wiring layer. External connections are formed on the polymer studs, the external connections each being electrically conductively connected to an associated one of the metallized plated-through holes.

The invention is based on the recognition of the fact that conventionally produced wiring with metallized plated-through holes can be placed into an injection mold as an insert part. When the substrate layer is injection molded on the top of the wiring, the plated-through holes then serve as feed channels for the molding of polymer studs on the underside of the wiring. The substrate layer makes it possible to produce a second wiring layer containing blind plated-through holes to the first wiring layer. The integration of the polymer studs into the plated-through holes permits very fine grids for the polymer studs and, in particular, optimally short connections between the external connections on the polymer studs and the first wiring layer. Since the blind plated-through holes between the first and second wiring layers also represent extremely short connections, a polymer stud grid array according to the invention is also eminently suitable for radio frequency applications.

The wiring placed into the injection mold promotes uniform diffusion of the injection molding compound in the injection mold, so that polymer stud grid arrays with a large surface area can be produced, or else a number of polymer stud grid arrays can be produced in one injection mold at the same time.

In accordance with an added feature of the invention, the blind plated-through holes have a funnel-shaped configuration and are formed at the same time as the substrate layer is injection molded. This allows particularly simple production of the blind holes for the blind plated-through holes in the substrate layer.

In accordance with an additional feature of the invention, the electrically insulating substrate is formed of a rigid printed circuit board material. This allows the use of conventional printed circuit board materials for the substrate. In particular, it is also possible to start with a base material coated with copper on both sides, in which plated-through holes are then made by mechanical drilling, by laser drilling or else by punching and are metallized by electroless and electrochemical deposition of copper, for example.

Alternatively, a flexible foil may be used as the substrate. In this case too, it is then possible to start with a flexible foil coated with copper on both sides. The finished polymer stud grid array may be of rigid or flexible configuration, according to the thickness of the substrate layer.

With the foregoing and other objects in view there is provided, in accordance with the invention, a method for producing a polymer stud grid array. The method includes the steps of:

providing a substrate being an electrically insulating substrate having a top side, an underside and holes formed therein;

producing a first wiring layer on said top side of the electrically insulating substrate; forming metallized plated-through holes in the holes of the substrate between the top side and the underside of the substrate;

applying an electrically insulating substrate layer on the top side of the substrate by injection molding, a material of the substrate layer passing through the metallized plated-through holes and forming integrally molded polymer studs on the underside of the substrate, the substrate layer also having blind holes formed therein on a top side of the substrate layer;

producing a second wiring layer on the substrate layer;

forming blind plated-through holes in the blind holes of the substrate layer, the blind plated-through holes extending down to the first wiring layer; and

producing external connections on the polymer studs, the external connections being electrically conductively connected to an associated one of the metallized plated-through holes.

In accordance with an added mode of the invention, there is the step of using a layer structuring process for forming the first wiring layer. This relates to a simple way of producing the first wiring layer. Besides direct laser structuring of the metal coating, this should also be understood as meaning laser structuring of an etch resist with subsequent etching of the metal coating. In this case, tin or tin/lead is particularly suitable as etch resist.

In accordance with another mode of the invention, there is the step of mettalizing over a whole area including the blind holes for forming the blind plated-through holes. Therefore, a single metallization operation is needed to provide the basis for producing the second wiring layer, the blind plated-through holes and the external connections on the polymer studs.

In accordance with a further mode of the invention, there are the steps of producing the second wiring layer by depositing a metal coating on a top surface of the substrate layer and laser structuring the metal coating, and producing the external connections by depositing a metal coating on the underside of the substrate and then laser structuring the metal coating. The second wiring layer and the external connections are produced in a particularly simple manner by laser structuring. In this case too, the term “laser structuring” should again be understood as meaning the two variants mentioned above.

Other features which are considered as characteristic for the invention are set forth in the appended claims.

Although the invention is illustrated and described herein as embodied in a polymer stud grid array and a method for producing such a polymer stud grid array, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a diagrammatic, sectional view through a substrate after plated-through holes have been made according to the invention;

FIG. 2 is a sectional view of the substrate after the plated-through holes and a first wiring layer have been produced;

FIG. 3 is a sectional view of the substrate after a substrate layer has been produced on the top and polymer studs have been produced on the underside by injection molding;

FIG. 4 is a sectional view of the structure after metallization over the whole area; and

FIG. 5 is a sectional view of the structure from FIG. 4 after a second wiring layer has been structured on the top and external connections have been structured on the polymer studs.

### DESCRIPTION OF THE PREFERRED EMBODIMENTS

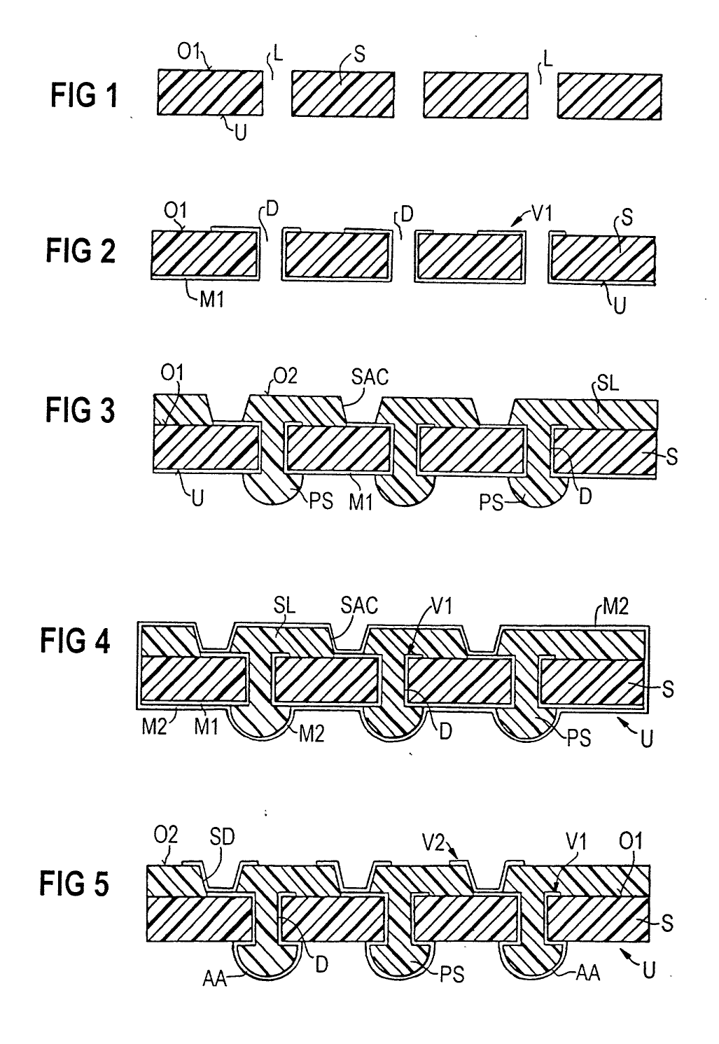

In all the figures of the drawing, sub-features and integral parts that correspond to one another bear the same reference symbol in each case. Referring now to the figures of the drawing in detail and first, particularly, to FIG. 1 thereof, there is shown a section through a substrate S in which holes L have been made for forming plated-through holes D. The holes L are produced by mechanical drilling, by laser drilling or by punching. By way of example, thermoplastics that are resistant to high temperatures, such as polyetherimide, polyethersulfone or liquid crystalline polymers (LCP), are suitable as a substrate material.

The substrate S shown in FIG. 1 is metallized over the whole area by a chemical and subsequent electrochemical deposition of metal, and the resultant metal coating M1 forms the metallized plated-through holes D, as shown in FIG. 2, between a top O1 and an underside U of the substrate S in the region of the holes L. FIG. 2 also shows a first wiring layer V1 on the top O1 of the substrate S. The wiring layer V1 having been produced, for example, by laser structuring the metal coating M1. In the illustrative embodiment shown, the metal coating M1 has been removed again in the region of the ends of the substrate S. Copper is particularly suitable as the metal coating M1.

The structure shown in FIG. 2 may alternatively be a base material plated with copper foil on both sides, such as a level 4 fire retardant epoxy glass composition (FR4) material which, after drilling, has been plated through by chemical and subsequently electrochemical deposition of copper in the region of the walls of the hole L.

The structure shown in FIG. 2 is placed into an injection mold (not shown in the drawing), into which an injection molding compound is fed from above under pressure. In the course of this, as FIG. 3 shows, a substrate layer SL is produced on the top O1 of the substrate S and on the wiring layer V1, and blind holes SAC in the form of truncated cones are formed in the substrate layer SL. During the injection molding operation, the plated-through holes D serve as feed channels for molding of polymer studs PS on the underside U of the substrate S. Thermoplastics that are resistant to high temperatures, such as polyetherimide or polyethersulfone, are suitable as material for the substrate layer SL and the polymer studs PS, although liquid crystalline polymers are preferably used.

The structure shown in FIG. 3 is metallized over the whole area by an electroless and electrochemical deposition of metal, the resultant second metal coating being denoted by M2, as shown in FIG. 4. In this case too, copper is again particularly suitable as the material for the metal coating M2.

As FIG. 5 shows, a second wiring layer V2 is formed on the top O2 of the substrate layer SL, preferably by laser structuring the metal coating M2, the second wiring layer V2 being electrically conductively connected to the first wiring layer V1 by blind plated-through holes SD. On the underside U of the substrate S, the metal coatings M1 and M2 are removed such that the remaining metal coating M2 on the polymer studs PS forms external connections AA. This operation is also preferably again performed by laser structuring.

FIG. 5 shows that the external connections AA on the polymer studs PS are electrically conductively connected to the plated-through holes D. The plated-through holes D for their part being electrically conductively connected to the second wiring layer V2 by the first wiring layer V1 and the blind plated-through holes SD. Chips can then be mounted on the second wiring layer V2 either using a flip-chip technique or using a bonding technique. The external connections AA on the polymer studs PS can be provided with a solder layer in the domed region, as detailed in International Patent Disclosure WO 96/09646, for example. Further details and features of a polymer stud grid array can also be found in WO 96/09646, the disclosed content of which is incorporated by reference herein and forms an integral part of the present application.

The second metal coating M2 on the end of the polymer stud grid array has been removed again in the illustrative embodiment shown in FIG. 5. Alternatively, the metal coating can remain and possibly form a shield together with other surfaces on the top O2 of the substrate layer SL.

In a departure from the illustrative embodiment described above, the first metal coating M1 on the underside U of the substrate S may also be removed at an even earlier point, for example at the method stage shown in FIG. 2 or preferably at the method stage shown in FIG. 3. This would then simplify formation of the external connections AA by structuring the second metal coating M2.

In the illustrative embodiment described, the polymer studs PS may have a diameter of 0.3 mm, for example, and a grid spacing of 0.5 mm between the individual polymer studs PS can then be provided.

I claim:

1. A polymer stud grid array, comprising:
an electrically insulating substrate having a top side and an underside, said electrically insulating substrate having metallized plated-through holes formed therein and extending between said top side and said underside;
a first wiring layer disposed on said top side of said electrically insulating substrate;
an injection-molded electrically insulating substrate layer disposed on said top side of said electrically insulating substrate and having a top surface, said substrate layer having blind plated-through holes formed therein;
polymer studs disposed in a planar fashion on said underside of said electrically insulating substrate and extending from said metallized plated-through holes, said polymer studs being formed from said substrate layer pushing through said metallized plated-through holes when said substrate layer is injection molded;
a second wiring layer disposed on said top surface of said substrate layer, said blind plated-through holes extending
between said first wiring layer and said second wiring layer; and
external connections formed on said polymer studs, said external connections each being electrically conductively connected to an associated one of said metallized plated-through holes.

2. The polymer stud grid array according to claim 1, wherein said blind plated-through holes have a funnel-shaped configuration and are formed at the same time as said substrate layer is injection molded.

3. The polymer stud grid array according to claim 1, wherein said electrically insulating substrate is formed of a rigid printed circuit board material.

4. The polymer stud grid array according to claim 1, wherein said electrically insulating substrate is formed from a flexible foil.

5. A method for producing a polymer stud grid array, which comprises the steps of:
providing a substrate being an electrically insulating substrate having a top side, an underside and holes formed therein;
producing a first wiring layer on said top side of the electrically insulating substrate;
forming metallized plated-through holes in the holes of the substrate between the top side and the underside of the substrate;
applying an electrically insulating substrate layer on the top side of the substrate by injection molding, a material of the substrate layer passing through the metallized plated-through holes and forming integrally molded polymer studs on the underside of the substrate, the substrate layer also having blind holes formed therein on a top side of the substrate layer;
producing a second wiring layer on the substrate layer;
forming blind plated-through holes in the blind holes of the substrate layer, the blind plated-through holes extending down to the first wiring layer; and
producing external connections on the polymer studs, the external connections being electrically conductively connected to an associated one of the metallized plated-through holes.

6. The method according to claim 5, which comprises forming the blind holes in a shape of a funnel and forming the blind holes at a same time as the substrate layer is injection molded.

7. The method according to claim 5, which comprises forming the substrate from a rigid printed circuit board material.

8. The method according to claim 5, which comprises forming the substrate from a flexible foil.

9. The method according to claim 5, which comprises using a layer structuring process for forming the first wiring layer.

10. The method according to claim 5, which comprises after the substrate layer and the polymer studs have been injection molded, mettalizing over a whole area including the blind holes for forming the blind plated-through holes.

11. The method according to claim 5, which comprises producing the second wiring layer by depositing a metal coating on a top surface of the substrate layer and laser structuring the metal coating.

12. The method according to claim 10, which comprises producing the external connections by depositing a metal coating on the underside of the substrate and then laser structuring the metal coating.
